(19) United States
(12) Patent Application Publication
(10) Pub. No.: US 2024/0314995 A1
(43) Pub. Date: Sep. 19, 2024

(54) METHOD AND CONTROL DEVICE FOR IDENTIFYING AT LEAST ONE FIXED SETUP FOR AN ASSEMBLY LINE

(71) Applicant: Siemens Aktiengesellschaft, München (DE)

(72) Inventors: Alexander Pfaffinger, München (DE); Christian Royer, Ottobrunn (DE)

(21) Appl. No.: 18/563,803

(22) PCT Filed: May 31, 2021
(86) PCT No.: PCT/EP2021/064574

§ 371 Date: Nov. 22, 2023

(51) Int. Cl. H05K 13/08; G05B 19/418

(52) U.S. Cl. CPC H05K 13/085; G05B 19/4189; G05B 2219/31054; G05B 2219/45026

(57) ABSTRACT

A method for identifying at least one fixed setup for an assembly line includes a circuit board double transport system of which the first transport track and second transport track transport double-sided circuit boards. The method includes acquiring a quantity of circuit board types which are each associated with double-sided circuit boards acquiring a quantity of component types acquiring a production time for synchronous population of the first and second side of each associated double-sided circuit; acquiring a production time for asynchronous population; acquiring a number of fixed setup clusters; assigning circuit board types to each fixed setup cluster; and optimizing the assignment process in such a way that the production time saving identified from the acquired production times of the synchronous and asynchronous population over all associated double-sided circuit boards is maximized.

### CROSS-REFERENCE TO RELATED APPLICATIONS

This application claims priority to PCT Application No. PCT/EP2021/064574, having a filing date of May 1, 2021, the entire contents of which are hereby incorporated by reference.

### FIELD OF TECHNOLOGY

The following relates to a method and a control device for determining at least one setup for an assembly line which is configured with a printed circuit board double transport system, and to an associated computer program product.

### BACKGROUND

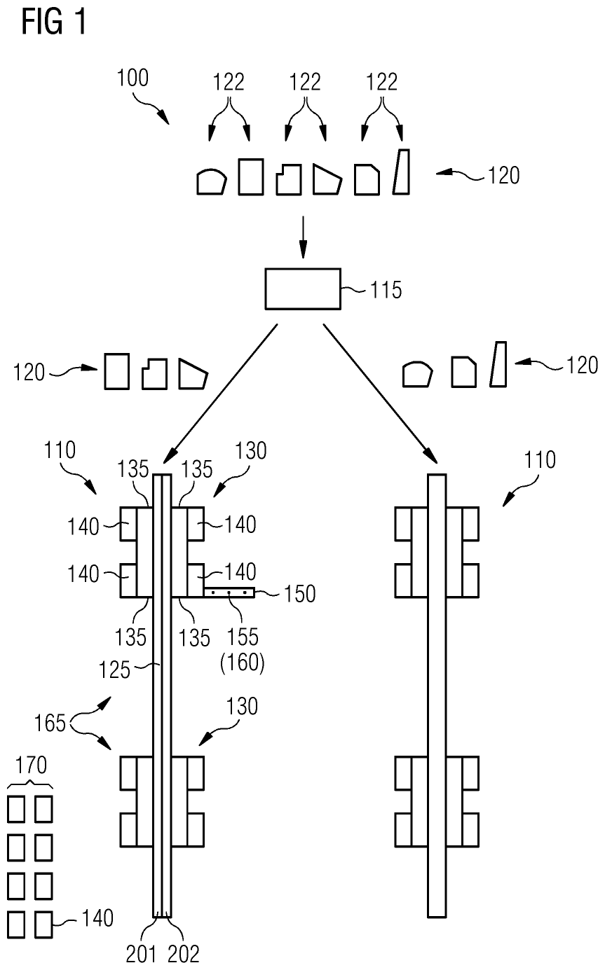

An assembly line is configured for populating a printed circuit board (LP) with a number of components. An assembly line of this kind is shown, for example, in FIG. 1 and will be explained in more detail below in relation to the exemplary embodiment. In the case of SMT (surface mounted technology), the components are mounted on printed circuit boards and soldered. A component placement machine situated on the assembly line comprises one or more component placement heads which are each configured to pick up components and position them in a predetermined position on the printed circuit boards which are located on a transport system. There are several types of head. In accordance with the “pick & place” principle, twin heads are used for example, these being able to pick up a few large components. In accordance with the “collect & place” principle, revolver heads are used for example, these being able to pick up a large number of small components.

During manufacture, the printed circuit board types to be manufactured are divided into setup families (“clusters”) for a planning horizon (approximately 1-5 days). Here, a setup family is a set of printed circuit board types which can be produced/manufactured with a predetermined number of components on the assembly line. The set of the component types required for this purpose is referred to as a setup and is typically accommodated in a set of shuttle tables. A shuttle table is typically equipped with the appropriate components in the preliminary setup for production and stripped again thereafter.

An assembly line can be configured with a printed circuit board double transport system. The printed circuit board double transport can produce a considerable increase in throughput. It allows simultaneous (synchronous) or alternating or staggered (asynchronous) transport of two printed circuit boards through a component placement machine mounted on the assembly line. In the case of the asynchronous manner of transport, a second identical printed circuit board type is moved into the component placement machine in a time-neutral manner while populating a printed circuit board. The secondary processing time sector caused by printed circuit board transport is therefore completely eliminated. The component placement capacity gain to be expected is between 10 and 30 percent, depending on the component content of the printed circuit board.

If double-sided printed circuit boards of one printed circuit board type are transported on this assembly line, the first side (top side) of the printed circuit board can then be populated with components on the first transport track, and the second side (bottom side) of the printed circuit board can be populated with components on the second transport track.

Initially all the printed circuit boards of a batch (printed circuit board type with a quantity to be manufactured; batch size is the quantity of printed circuit boards of one printed circuit board type to be manufactured) are usually populated with components on one side (e.g., the top side). Then, all the printed circuit boards of the batch are populated with components on the other side (e.g., the bottom side). This component placement mode it is referred to as asynchronous. This is usually done using a component setup of the assembly line.

If the assembly line exhibits synchronous double transport, it is possible to populate the top side of a printed circuit board of the batch on one transport track and at the same time to populate the bottom side of the printed circuit board of the batch on the other transport track, as a result of which the total component placement content on the processing unit is increased. This component placement mode is referred to as synchronous.

Synchronous operation can considerably reduce the production times. This is based on the following two effects.
(1) An assembly line has what is referred to as an external cycle time (e.g., owing to a printer or furnace). In a manufacturing plant, this external cycle time is typically 16 s. If the cycle time of a printed circuit board side in the asynchronous mode is below 16 seconds, this results in an unproductive “waiting time” of the assembly line. This waiting time can be reduced in the synchronous mode and therefore the total production time is also lowered. Simplified example: 1000 pieces. 16 s external line cycle time.
   Top side 10 s cycle time, bottom side 6 s cycle time

Production time in the asynchronous mode=1000*(16 s+16 s)=32 000 s.
Top side and bottom side cycle time in the synchronous mode: 16 s cycle time

Production time in the synchronous mode=1000*16 s=16 000 s
(2) If the component placement content of one side places more load on the revolver heads (large number of small components) and the component placement content of the other side places more load on the twin heads (a few large components), only the respective component placement heads of one type of head of the assembly line are subject to loading, while the other heads wait in an unproductive manner. In the synchronous mode, this then results in a more uniform and higher loading on all the component placement heads of the assembly line and therefore in a lower total production time.

When forming the setup families mentioned at the outset for synchronous assembly lines, the best printed circuit board types should be selected so that the production time saving compared to operation for printed circuit board population in the asynchronous mode is as high as possible.

### SUMMARY

An aspect relates to specify a method that is improved in comparison to the conventional art mentioned at the outset and to specify an improved control device.

An aspect relates to a method for determining at least one fixed setup for an assembly line which is configured with a printed circuit board double transport system of which the first transport track transports double-sided printed circuit boards of a printed circuit board type of which the first side is populated, and of which the second transport track transports double-sided printed circuit boards of the printed circuit board type (primarily of the same printed circuit board type) of which the second side is populated, wherein each fixed setup comprises a number of component types that is sufficient to populate the printed circuit boards of a fixed-setup setup family, which is associated with this fixed setup, of printed circuit board types, wherein the at least one fixed setup remains unchanged during the planning horizon and can be used several times on the assembly line, wherein the method comprises the following steps:
detecting a set of printed circuit board types each with allocated double-sided printed circuit boards which are intended to be populated on the assembly line within the planning horizon;
detecting a set of component types together with their space requirement in tracks in at least one component feed device;
detecting a production time for simultaneous, referred to as synchronous, population of the first and second side of each allocated double-sided printed circuit board on the first and second transport track;
detecting a production time for staggered, referred to as asynchronous, population of the first and second side of each allocated double-sided printed circuit board on the first and second transport track;
detecting a number of fixed-setup setup families, wherein each fixed-setup setup family comprises a set of printed circuit board types of which the printed circuit boards can be populated with the components of the component types of the fixed setup on the assembly line;
assigning printed circuit board types to each fixed-setup setup family, wherein all the components for populating a printed circuit board of a printed circuit board type of the assigned printed circuit board types have the space they require in the tracks available in the fixed setup and are set up in the fixed setup; and
optimizing the assignment process in such a way that the production time saving, which is identified from the detected production times of the synchronous and asynchronous population over all the allocated double-sided printed circuit boards, is maximized.

On account of setting up shuttle tables and equipment that is additionally required for them, an assembly line can, in practice, be operated efficiently in the synchronous mode when there is only a fixed setup and no variable setups have to be constructed.

A fixed-setup setup family comprises a set of printed circuit board types of which the printed circuit boards can be populated with the components of the component types of the fixed setup on the assembly line.

One development of embodiments of the invention provides that, for each fixed-setup setup family, the printed circuit boards of the assigned printed circuit board types have the same printed circuit board width, so that the printed circuit boards fit into the transport track with respect to the transport track width.

Therefore, only printed circuit boards of one printed circuit board width should be used in order to prevent width adjustments on the assembly line. In addition, it is particularly advantageous when a large number of printed circuit boards are used.

The sum of the production times of the printed circuit board types of a fixed-setup setup family should fall below a prespecifiable upper limit and/or exceed a prespecifiable lower limit.

Optimization is prior carried out by means of mixed integer programming.

Finally, the printed circuit boards can be populated on the assembly line by means of the at least one fixed setup. Printed circuit boards should be populated with just one fixed setup on the assembly line.

The economic benefits and savings on equipment and production time are very high.

A further aspect of embodiments of the invention provides a control device. The control device is designed for determining at least one fixed setup for an assembly line which is configured with a printed circuit board double transport system of which the first transport track transports double-sided printed circuit boards of a printed circuit board type of which the first side can be populated, and of which the second transport track can transport double-sided printed circuit boards of the (same) printed circuit board type of which the second side can be populated, wherein each fixed setup comprises a number of component types that is sufficient to populate the printed circuit boards of a fixed-setup setup family, which is associated with this fixed setup, of printed circuit board types, wherein the at least one fixed setup remains unchanged during the planning horizon and can be used several times on the assembly line, wherein the control device is designed to execute the following steps:
detecting a set of printed circuit board types each with allocated double-sided printed circuit boards which are intended to be populated on the assembly line within the planning horizon;
detecting a set of component types together with their space requirement in tracks in at least one component feed device;
detecting a production time for simultaneous, referred to as synchronous, population of the first and second side of each allocated double-sided printed circuit board on the first and second transport track;
detecting a production time for staggered, referred to as asynchronous, population of the first and second side of each allocated double-sided printed circuit board on the first and second transport track;
detecting a number of fixed-setup setup families, wherein each fixed-setup setup family comprises a set of printed circuit board types of which the printed circuit boards can be populated with the components of the component types of the fixed setup on the assembly line;
assigning printed circuit board types to each fixed-setup setup family, wherein all the components for populating a printed circuit board of a printed circuit board type of the assigned printed circuit board types have the space they require in the tracks available in the fixed setup and are set up in the fixed setup; and
optimizing the assignment process in such a way that the production time saving, which is identified from the detected production times of the synchronous and asynchronous population over all the allocated double-sided printed circuit boards, is maximized.

The units and the device which are configured to execute such method steps can be implemented using hardware, firmware and/or software.

A further aspect of embodiments of the invention is a computer program product (non-transitory computer readable storage medium having instructions, which when executed by a processor, perform actions) with program code means for carrying out the method when it runs on a control device of the type mentioned above or is stored on a computer-readable storage medium.

The computer program or computer program product may be stored on a computer-readable storage medium. The computer program or computer program product may be written in a standard programming language (e.g. C++, Java). The processing device may comprise a commercially available computer or server having appropriate input, output and storage means. This processing device may be integrated in the control device or in the means thereof.

The control device and the computer program (product) can be developed or designed analogously to the method mentioned above and the developments thereof.

### BRIEF DESCRIPTION

Some of the embodiments will be described in detail, with reference to the following figures, wherein like designations denote like members, wherein:

FIG. 1 shows a processing system for processing workpieces;

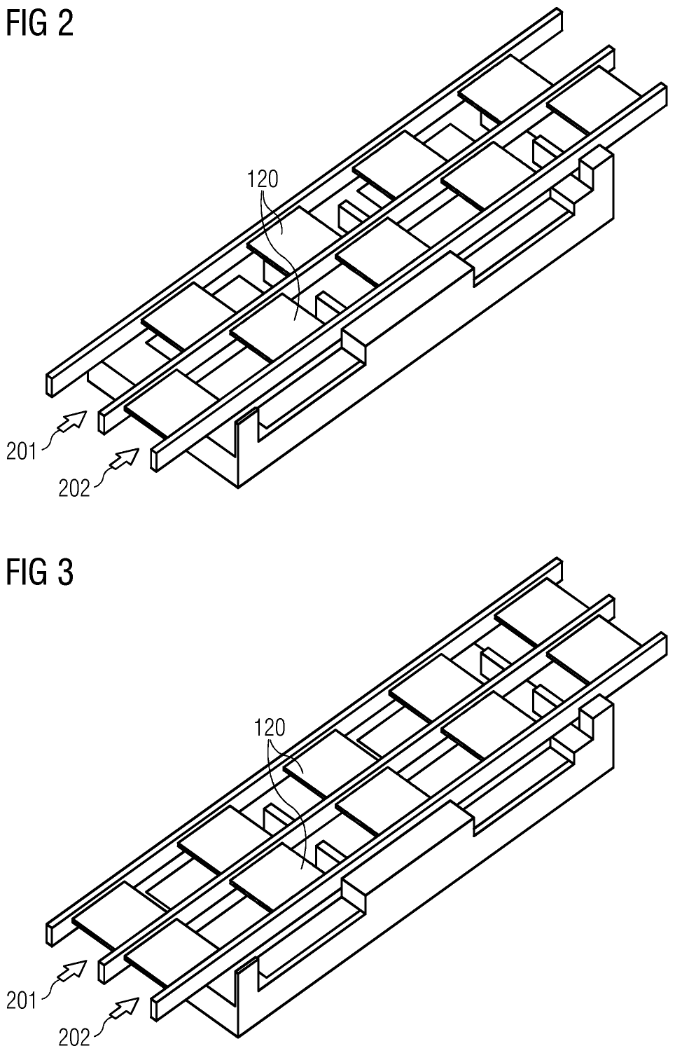

FIG. 2 shows the asynchronous mode described at the outset; and

FIG. 3 shows the synchronous mode explained at the outset.

### DETAILED DESCRIPTION

FIG. 1 shows a component placement system 100. The component placement system 100 comprises one or more assembly lines 110 and a control device 115. Each assembly line 110 comprises a transport system 125 and one or more component placement machines 130. Each component placement machine 130 comprises one or more component placement heads 135, which are each configured to pick up components 155 from a shuttle table 140 and position them in a predetermined position on the printed circuit board 120 that is located on the transport system 125. The transport system is configured as a printed circuit board double transport system of which the first transport track 201 transports double-sided printed circuit boards 120 of a printed circuit board type 122 of which the first side is populated, and of which the second transport track 202 transports double-sided printed circuit boards 120 of the printed circuit board type 122 of which the second side is populated.

During the component placement process, the printed circuit board 120 is typically stationary with respect to the component placement machine 130. The shuttle tables 140 each comprise a large number of feed devices 150, of which only one is shown by way of example in FIG. 1. Each component feed device 150 keeps ready a reserve of components 155 of a predetermined component type 160. The component feed device 150 has a capacity for the components 155, which is typically expressed in tracks. A track is typically 8 mm wide and the number of tracks of each component feed device 150 is limited, for example to 40. Components 155 of the same component type 160 are typically provided in a belt, on a tray or in a tube. Each component type 160 requires a predetermined number of tracks, which typically have to adjoin one another, on the component feed device 150.

Each component feed device 150 can be configured to keep ready different components 155 and different component feed devices 150 can typically be attached to a shuttle table 140. If a component 155 of a component type 160 that is not present in one of the shuttle tables 140 is required on the component placement machine 130, one of the attached shuttle tables 140 is typically not provided with the required components 155, but rather exchanged completely for another, appropriately equipped shuttle table 140. Setting up a shuttle table 140 to be switched in with components 155 is referred to as preliminary setup and can require a processing time in the range of hours.

Since changing shuttle tables 140 on the assembly line 110 is typically associated with a production stoppage, efforts are made to change the shuttle tables 140 as rarely as possible.

To populate a predetermined set of printed circuit boards 120, setups can be formed which each comprise reserves of components 155 of predetermined component types 160, wherein each of the printed circuit boards 120 of the set can be completely populated with components 155 of the setup. A setup can be implemented by a number of shuttle tables 140. A fixed setup 165, of which the shuttle tables 140 are attached to the assembly line 110, and a variant setup 170, of which the shuttle tables 140 are separated from the assembly line 110, are formed in the illustration of FIG. 1. One or more fixed setups can be provided. A desired case is to manage without variant setups 170, in particular when a printed circuit board double transport system in the synchronous mode is used.

The fixed setup 165 is configured to remain unchanged with respect to its component types 160 at least during a planning horizon, which can last for half a year or one year, for example. Components 155 can thus be refilled at the shuttle tables 140 of the fixed setup 165 as required, but the assignment of component types 160 to tracks of the shuttle tables 140 remains unchanged. If multiple fixed setups 165 are provided, these can be exchanged with one another or with one of the variant setups 170 within the planning horizon.

A variant setup 170 on the other hand is configured to pick up components 155 of different component types 160 during the planning horizon but remains intact only temporarily. To this end, the shuttle tables 170, while they are not attached to the assembly line 110, are typically stripped of components 155 of predetermined component types 160 and filled with components 155 of other component types 160. This changeover may involve a considerable amount of manual work and be time-consuming.

The control device 115 assigns printed circuit board types 122, of which the assigned printed circuit boards 120 are intended to be populated on the assembly line 110, to a setup family. A setup family is a set of printed circuit board types 122 of which the printed circuit boards 120 can be completely populated with components 155 that are provided in the assigned setup 165, 170. A setup family is typically assigned to precisely one setup 165, 170 and vice versa.

FIGS. 2 and 3 each show a detail of a printed circuit board double transport system which has two transport tracks 201 and 202 and passes through a component placement machine 130. FIG. 2 shows the asynchronous mode described at the outset. FIG. 3 shows the synchronous mode explained at the outset.

Using the following optimization method, the assignment of printed circuit board types to one or more fixed-setup setup families, wherein all the components for populating a printed circuit board of a printed circuit board type of the assigned printed circuit board types have the space they require in the tracks available in the fixed setup and are set up in the fixed setup, can be carried out.

A specific case of optimization methods is linear optimization. It is concerned with the optimization of linear target functions over a set which is limited by linear equations and inequations. It is the basis of the solution methods of (mixed) integer linear optimization. What is referred to as a solver is a generic term for specific mathematical computer programs that can solve mathematical problems numerically. In connection with MILP (mixed integer linear programming), standard solvers such as e.g., CPLEX, Scip, Gurobi, Xpress can be used for IP programs (integer optimization models).

A starting configuration is typically prespecified, this being led to an objective result iteratively by means of optimization. In the example, the objective is that the production time saving, which is identified from the detected production times of the synchronous and asynchronous population over all the allocated double-sided printed circuit boards, is maximized.

An MILP model for determining fixed-setup setup families for a specified assembly line to be operated in the synchronous mode is proposed below. The approach is based on mixed integer linear optimization.

The setup families for the synchronous mode of the line are formed such that the production time saving is maximized compared to manufacture of the assemblies in the asynchronous mode. Various restrictions have to be complied with here:
Complying with a minimum production time, which ensures that the line is not underloaded.
Complying with a maximum production time, which ensures that the line is not overloaded.
A setup family must not contain any different printed circuit board widths.
The component setup of a setup family has to be able to be set up on the line.

The following designations apply in the MILP formulation.

### Indices

C set of the component types;
R set of the assemblies (synchronous boards with a top side and a bottom side);
R_{c} set of the assemblies with component type c; and
Cl set of the fixed setups/fixed-setup families Cl.

### Parameters

Width_{c} space taken up by a component type c in tracks;
LineCap number of tracks of the component types that have space in the setup of a setup family;
Upper TimeLimit upper production time limit for all assemblies allocated to the assembly line;
Lower TimeLimit lower production time limit for all assemblies allocated to the assembly line;
TimeSyncᵣ total production time for the assembly r if it is manufactured in the synchronous mode;
Time ASyncᵣ total production time for the top side and bottom side of the assembly r if they are manufactured in the asynchronous mode; and
BoardWidthᵣ printed circuit board width of assembly r.

### Binary Variables

assign_{r,cl} variable that indicates whether an assembly r is assigned to the setup family cl. (In this case, it takes the value 1, otherwise the value 0); and
setup_{c,cl} variable that indicates whether the component type c has to be set up in the setup of the setup family cl. (In this case, it takes the value 1, otherwise the value 0);

### Objective Function:

$$Maximize {\sum }_{cl ∈ Cl} {\sum }_{r ∈ R} {assign}_{r , cl} ( T i m e A s y n {c}_{r} - T i m e S y n {c}_{r} )$$

### Secondary Conditions:

(1) Each assembly type must be assigned to at most one setup family.

$$\begin{matrix}{\sum }_{cl ∈ Cl} {assign}_{r , cl} \leq 1 \\ r ∈ R\end{matrix}$$

(2) The component types of the assemblies of a setup family have to fit into a setup.

$$\begin{matrix}{\sum }_{c ∈ C} {Width}_{c} {setup}_{c , cl} \leq LineCap \\ cl ∈ Cl\end{matrix}$$

(3) All component types of a setup family have to be set up in the setup of the setup family.

$$\begin{matrix}{\sum }_{τ ∈ R c} a s s i g {n}_{r , cl} \leq \vert {R}_{c} \vert {setup}_{c , cl} \\ c ∈ C , C l ∈ C l\end{matrix}$$

(4) The sum of the production times of the assembly types of a setup family must not exceed the upper production time limit.

$${\sum }_{cl ∈ Cl} {\sum }_{r ∈ R} {assign}_{r , cl} T i m {e}_{r} \geq UpperTimeLimit$$

(5) The sum of the production times of the assembly types of a setup family must not fall below the lower production time limit.

$${\sum }_{cl ∈ Cl} {\sum }_{r ∈ R} {assign}_{r , cl} T i m {e}_{r} \geq LowerTimeLimit$$

(6) All assemblies allocated to a setup family have to have the same printed circuit board width

$$\begin{matrix}{assign}_{r , cl} + {assign}_{{r}^{′} cl} \leq 1 \\ cl ∈ Cl , r , {r}^{′} ∈ R , B {oardWidth}_{r} \neq B {oardWidth}_{{r}^{′}}\end{matrix}$$

(7) Variable restrictions

$$\begin{matrix}{assign}_{r , cl} ∈ \{ 0 , 1 \} & r ∈ R , c l ∈ C l \\ {setup}_{c , cl} ∈ \{ 0 , 1 \} & c ∈ C , c l ∈ C l\end{matrix}$$

In the example, two of 15 assembly lines were able to be saved by the production time reductions achieved by the method according to embodiments of the invention in a printed circuit board production plant.

Although embodiments of the invention have been illustrated and described in more detail by the exemplary embodiment, embodiments of the invention are not restricted by the examples disclosed, and other variations may be derived herefrom by a person skilled in the art without departing from the scope of protection of embodiments of the invention.

The processes or method sequences described above may be implemented on the basis of instructions that are available on computer-readable storage media or in volatile computer memories (referred to collectively as computer-readable memories below). Computer-readable memories are, for example, volatile memories such as caches, buffers or RAM and non-volatile memories such as removable data storage media, hard disks, etc.

The functions or steps described above may be present in this case in the form of at least one instruction set in/on a computer-readable memory. In this case, the functions or steps are not tied to a particular instruction set or to a particular form of instruction sets or to a particular storage medium or to a particular processor or to particular execution schemes and may be executed alone or in any desired combination by means of software, firmware, microcode, hardware, processors, integrated circuits, etc. In this case, a wide variety of processing strategies may be used, for example serial processing by an individual processor or multiprocessing or multitasking or parallel processing, etc.

The instructions may be stored in local memories, but it is also possible to store the instructions in a remote system and to access them via a network.

“Computer-aided” in connection with embodiments of the invention may be understood to mean, for example, an implementation of the method in which, in particular, a processor, which may be part of the control device or unit, executes at least one method step of the method.

The term “processor”, “central signal processing”, “control unit” or “data evaluation means” as used here comprises processing means in the broadest sense, that is to say for example servers, universal processors, graphics processors, digital signal processors, application-specific integrated circuits (ASICs), programmable logic circuits such as FPGAs, discrete analog or digital circuits and any combination thereof, including all other processing means known to a person skilled in the art or developed in the future. In this case, processors may consist of one or more devices or apparatuses or units. If a processor consists of a plurality of devices, they may be designed or configured for the parallel or sequential processing or execution of instructions. A “storage unit” in connection with embodiments of the invention may be understood to mean, for example, a memory in the form of main memory (random access memory, RAM) or a hard disk.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A method for determining at least one fixed setup for an assembly line which is configured with a printed circuit board double transport system of which the first transport track transports double-sided printed circuit boards of a printed circuit board type of which the first side is populated, and of which the second transport track transports double-sided printed circuit boards of the printed circuit board type of which the second side is populated, wherein each fixed setup comprises a number of component types that is sufficient to populate the printed circuit boards of a fixed-setup setup family, which is associated with this fixed setup, of printed circuit board types, wherein the at least one fixed setup remains unchanged during the planning horizon and can be used several times on the assembly line, wherein the method comprises the following steps:
detecting a set of printed circuit board types each with allocated double-sided printed circuit boards which are intended to be populated on the assembly line within the planning horizon;
detecting a set of component types together with their space requirement in tracks in at least one component feed device;
detecting a production time for simultaneous, referred to as synchronous, population of the first and second side of each allocated double-sided printed circuit board on the first and second transport track;
detecting a production time for staggered, referred to as asynchronous, population of the first and second side of each allocated double-sided printed circuit board on the first and second transport track;
detecting a number of fixed-setup setup families, wherein each fixed-setup setup family comprises a set of printed circuit board types of which the printed circuit boards can be populated with the components of the component types of the fixed setup on the assembly line;
assigning printed circuit board types to each fixed-setup setup family, wherein all the components for populating a printed circuit board of a printed circuit board type of the assigned printed circuit board types have the space they require in the tracks available in the fixed setup and are set up in the fixed setup; and
optimizing the assignment process in such a way that the production time saving, which is identified from the detected production times of the synchronous and asynchronous population over all the allocated double-sided printed circuit boards, is maximized.

2. The method as claimed in claim 1, wherein, for each fixed-setup setup family, the printed circuit boards of the assigned printed circuit board types have the same printed circuit board width, so that the printed circuit boards fit into the transport track with respect to the transport track width.

3. The method as claimed in claim 1, wherein printed circuit boards with only one fixed setup are populated on the assembly line.

4. The method as claimed in claim 1, wherein the sum of production times of the printed circuit board types of a fixed-setup setup family falls below a pre-specifiable upper limit.

5. The method as claimed in claim 1, wherein the sum of production times for the printed circuit board types of a fixed-setup setup family exceeds a pre-specifiable lower limit.

6. The method as claimed in claim 1, wherein optimization is carried out by mixed integer programming.

7. A control device for determining at least one fixed setup for an assembly line which is configured with a printed circuit board double transport system of which the first transport track transports double-sided printed circuit boards of a printed circuit board type of which the first side can be populated, and of which the second transport track transports double-sided printed circuit boards of the printed circuit board type of which the second side can be populated, wherein each fixed setup comprises a number of component types that is sufficient to populate the printed circuit boards of a fixed-setup setup family, which is associated with this fixed setup, of printed circuit board types, wherein the at least one fixed setup remains unchanged during the planning horizon and can be used several times on the assembly line, wherein the control device is designed to execute the following steps:
detecting a set of printed circuit board types each with allocated double-sided printed circuit boards which are intended to be populated on the assembly line within the planning horizon;
detecting a set of component types together with their space requirement in tracks in at least one component feed device;
detecting a production time for simultaneous, referred to as synchronous, population of the first and second side of each allocated double-sided printed circuit board on the first and second transport track;
detecting a production time for staggered, referred to as asynchronous, population of the first and second side of each allocated double-sided printed circuit board on the first and second transport track;
detecting a number of fixed-setup setup families, wherein each fixed-setup setup family comprises a set of printed circuit board types of which the printed circuit boards can be populated with the components of the component types of the fixed setup on the assembly line;
assigning printed circuit board types to each fixed-setup setup family, wherein all the components for populating a printed circuit board of a printed circuit board type of the assigned printed circuit board types have the space they require in the tracks available in the fixed setup and are set up in the fixed setup; and
optimizing the assignment process in such a way that the production time saving, which is identified from the detected production times of the synchronous and asynchronous population over all the allocated double-sided printed circuit boards, is maximized.

8. The control device as claimed in claim 7, wherein, for each fixed-setup setup family, the printed circuit boards of the assigned printed circuit board types have the same printed circuit board width, so that the printed circuit boards fit into the transport track with respect to the transport track width.

9. A computer program product, comprising a computer readable hardware storage device having computer readable program code stored therein, said program code executable by a processor of a computer system to implement a method with program code carrying out the method as claimed in claim 1 when it is executed on a processor.

10. The computer program product as claimed in claim 9, wherein the control device is a control device for determining at least one fixed setup for an assembly line which is configured with a printed circuit board double transport system of which the first transport track transports double-sided printed circuit boards of a printed circuit board type of which the first side can be populated, and of which the second transport track transports double-sided printed circuit boards of the printed circuit board type of which the second side can be populated, wherein each fixed setup comprises a number of component types that is sufficient to populate the printed circuit boards of a fixed-setup setup family, which is associated with this fixed setup, of printed circuit board types, wherein the at least one fixed setup remains unchanged during the planning horizon and can be used several times on the assembly line, wherein the control device is designed to execute the following steps:
detecting a set of printed circuit board types each with allocated double-sided printed circuit boards which are intended to be populated on the assembly line within the planning horizon;
detecting a set of component types together with their space requirement in tracks in at least one component feed device;
detecting a production time for simultaneous, referred to as synchronous, population of the first and second side of each allocated double-sided printed circuit board on the first and second transport track;
detecting a production time for staggered, referred to as asynchronous, population of the first and second side of each allocated double-sided printed circuit board on the first and second transport track;
detecting a number of fixed-setup setup families, wherein each fixed-setup setup family comprises a set of printed circuit board types of which the printed circuit boards can be populated with the components of the component types of the fixed setup on the assembly line;
assigning printed circuit board types to each fixed-setup setup family, wherein all the components for populating a printed circuit board of a printed circuit board type of the assigned printed circuit board types have the space they require in the tracks available in the fixed setup and are set up in the fixed setup; and
optimizing the assignment process in such a way that the production time saving, which is identified from the detected production times of the synchronous and asynchronous population over all the allocated double-sided printed circuit boards, is maximized.

11. The computer program product of claim 10, wherein the control device for each fixed-setup setup family, the printed circuit boards of the assigned printed circuit board types have the same printed circuit board width, so that the printed circuit boards fit into the transport track with respect to the transport track width.
